(19) United States
(12) Patent Application Publication
(10) Pub. No.: US 2024/0125903 A1
(43) Pub. Date: Apr. 18, 2024

(54) LIDAR TRANSMITTER AND LIDAR SYSTEM WITH CURVED LASER ARRANGEMENT AND MANUFACTURING METHOD OF THE SAME

(71) Applicant: ams Sensors Asia Pte. Ltd, SINGAPORE (SG)

(72) Inventor: Ho Hoai Duc NGUYEN, Munich (DE)

(21) Appl. No.: 17/769,244

(22) PCT Filed: Oct. 9, 2020
(86) PCT No.: PCT/SG2020/050576

§ 371 Date: Apr. 14, 2022

Related U.S. Application Data
(60) Provisional application No. 62/916,915, filed on Oct. 18, 2019.

(51) Int. Cl. G01S 7/481; H01S 5/02; H01S 5/02253; H01S 5/42

(52) U.S. Cl. CPC G01S 7/4815; G01S 7/4816; H01S 5/0207; H01S 5/0215; H01S 5/02253; H01S 5/423

(57) ABSTRACT

A LIDAR transmitter system comprising an array of laser energy sources, the laser energy sources being arranged on a first curved surface and being configured to emit laser energy towards a LIDAR target. The LIDAR transmitter system further comprising at least a first lens arranged in the optical path between the array of laser energy sources and the LIDAR target, wherein the first curved surface is positioned at an image plane of the first lens. Further, a method of manufacturing the LIDAR transmitter system comprises the steps of: measuring a field curvature of a first lens; arranging a plurality of laser energy sources as an array on a flat surface; heating the flat surface to increase malleability of the flat surface; applying a pressure to predetermined regions of the flat surface to convert the flat surface to a curved surface, the curvature of the curved surface following the field curvature of the first lens; cooling the curved surface; and positioning the curved surface at an image plane of the first lens.

### TECHNICAL FIELD OF THE DISCLOSURE

The disclosure relates to LIDAR systems and methods, particularly but not exclusively, to a LIDAR transmitter system, a LIDAR system, and a method for emitting a LIDAR signal.

### BACKGROUND OF THE DISCLOSURE

LIDAR (Light Detection and Ranging) is a technique of measuring a distance to a target. The target is illuminated with laser light emitted from a LIDAR transmitter system and the reflected laser light is detected with a sensor or LIDAR receiver system. A time-of-flight measurement is made to establish the distance between the LIDAR system and different points on the target to build up a three-dimensional representation of the target. The target could be an object, plurality of objects or a whole scene in the field of view of the LIDAR system.

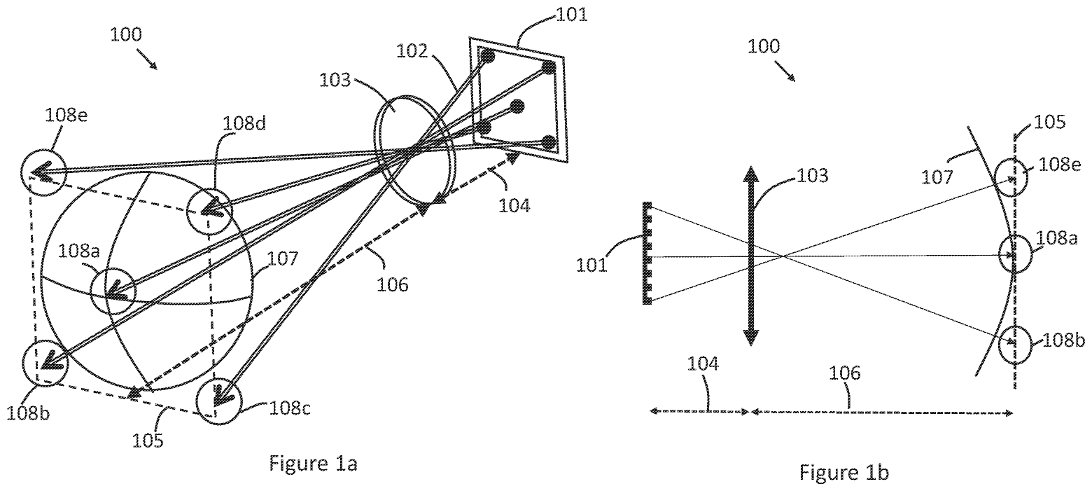

An example of a known LIDAR transmitter system 100 is illustrated in FIG. 1a. The known LIDAR transmitter system 100 includes a laser source 101 emitting laser energy 102 through a lens 103 towards a LIDAR target. The laser source 101 is typically positioned in a focal plane of the lens at an effective focal length 104. In real world settings, the lens 103 is not perfect and accordingly causes optical distortions in the laser energy passing through it.

A known type of optical aberration is field curvature (also known as Petzval field curvature). Field curvature is an optical aberration that occurs in lenses, mirrors and other optical components and may generally be described as the phenomenon in which a flat object normal to the optical axis (or a non-flat object past the hyperfocal distance) cannot be brought properly into focus on a flat image plane. Instead, the effect of the aberration is to cause a curvature in the image “plane” (i.e. the field of focus of the lens). This curved image “plane” or curvature in the field of focus of the lens, mirror or other optical component is known as a Petzval surface. The strength of the field curvature depends on distance from the optical axis and the optical parameters of the optical system, such as for example lens thickness. Accordingly, at the optical axis, the effect is negligible but as the distance from the optical axis increases, the effect increases. The field curvature aberration may be considered to be a mapping of points of the object onto a curved surface rather than onto a flat surface.

In the known LIDAR transmitter system 100 of FIG. 1a, the lens 103 causes a field curvature which distorts the ideal, flat image plane 105 by giving it a curvature at a distance 106 from the lens. As described above, the curved image “plane” 107 is known as a Petzval surface. All points on this curved surface 107 are in focus, whereas any points not on this surface 107 are not in focus.

The five illustrative ray paths from the LIDAR transmitter system 100 in FIG. 1a intersect the ideal, flat image plane 105 at five distinct points 108a, 108b, 108c, 108d, 108e. One of the points 108a intersects the ideal, flat image plane 105 at the optical axis and so the field curvature is negligible (in other words, the ideal flat image plane 105 and the Petzval surface 107 share a common point where they intersect the optical axis). The other points 108b, 108c, 108d, 108e intersect the flat image plane 105 at a distance away from the optical axis where the effect of the field curvature is greater. These points 108b, 108c, 108d, 108e are accordingly not on the Petzval surface 107 and so are not in focus.

FIG. 1b illustratively shows a side view of the LIDAR transmitter system 100 of FIG. 1a. As described above, the aberration caused by the lens causes the ideal, flat image plane 105 to be curved, the resulting surface 107 known as a Petzval surface. Accordingly, not all of the emitted laser energy is focussed at the ideal, flat image plane 105. Instead, at least a portion of the total laser energy emitted by the LIDAR transmitter is out of focus at the ideal, flat image plane 105. Thus, when the LIDAR target is a surface corresponding to the ideal, flat image plane, only the portion of the laser energy beam hitting the LIDAR target along the optical axis is in focus and has an ideal beam intensity with minimal beam divergence. The rest of the laser beam, particularly at the periphery of the beam, is out of focus and accordingly has a lower beam intensity and higher beam divergence.

The effective range of a LIDAR system depends in part on the intensity of the beam hitting the LIDAR target. Specifically, the strength of the signal detected at the LIDAR receiver system typically requires at least a minimum beam intensity hitting the LIDAR target (i.e. the intensity must be high enough for its reflection to be detected at the LIDAR receiver system). The above described field curvature aberration and consequential reduction in beam intensity at the periphery of the beam results in a drop in effective LIDAR range at the periphery of the beam.

Similarly, the greater the beam divergence at a LIDAR target, the less granular the resolution of the LIDAR system. Accordingly, the greater beam divergence at the periphery of the beam caused by the field curvature aberration worsens the resolution of the LIDAR system for LIDAR targets in the periphery of the beam.

For example, if the effective LIDAR range and resolution of the LIDAR system 100 of FIG. 1a along the optical axis (i.e. along the central ray path 108a) is 60 meters and 0.1 degrees respectively, then the field curvature aberration may cause the effective LIDAR range and resolution at the periphery of the emitted laser energy (i.e. of the other ray paths 108b, 108c, 108d, 108e) to be 30 meters and 0.4 degrees.

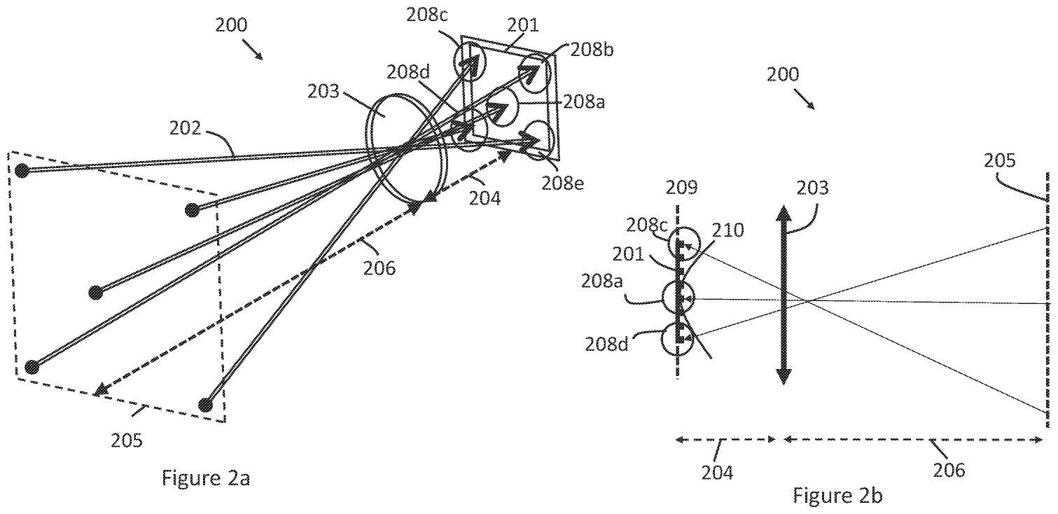

A corresponding effect may occur to energy reflected off the LIDAR target as it enters through a corresponding lens and hits an array of photodetectors of a LIDAR receiver system 200, as shown illustratively in FIGS. 2a and 2b. In the example of FIG. 2a, energy 202 reflected from a LIDAR target 205 at a position corresponding to the ideal, flat image plane of the LIDAR transmitter system travels a distance 206 to and through a lens 203 and hits an array of photodetectors 201 of the LIDAR receiver system 200. The photodetectors are typically arranged on a flat surface at an effective focal length 204 from the lens and corresponding to the ideal, flat image (i.e. focal) plane 209 of the lens 203. In the example of FIG. 2a, five illustrative ray paths 208a, 208b, 208c, 208d, 208e of reflected energy are shown hitting the flat plane of the photodetectors of the LIDAR receiver system 200. As shown in FIG. 2b, the field curvature aberration of the lens 203 distorts the ideal, flat image plane 209 of the lens 203 to be a curved surface 210 (namely a Petzval surface). As described above, only points on the curved surface 210 are in focus. Accordingly, reflected energy along some of the ray paths 208b, 208c, 208d, 208e are not in focus when they hit the photodetectors arranged on the flat surface corresponding to the ideal, flat image plane 209 of the lens 203. This field curvature aberration at the LIDAR receiver system 200 further reduces the effective LIDAR range and resolution of the LIDAR system.

It is therefore an aim of the present disclosure to provide a LIDAR transmitter system, LIDAR system, and method that addresses one or more of the problems above or at least provides a useful alternative.

### SUMMARY

In general, this disclosure proposes to overcome the above problems by curving the surface on which the laser energy sources arranged to match the field curvature caused by the lens. This arrangement compensates for and/or entirely counters the aberration induced curving of the image plane of the lens. Accordingly, the laser energy hits the LIDAR target in focus in the entire image plane, and not just at the point along the optical axis. Thus, when this arrangement is used in a LIDAR transmitter system, the effective LIDAR range and resolution remain constant irrespective of distance from the optical axis at the LIDAR target in the image plane. Accordingly, there is no drop in range or resolution at the periphery of the output laser energy emission because the beam intensity and divergence are constant at all distances from the optical axis.

According to one aspect of the present disclosure, there is provided a LIDAR transmitter system comprising: an array of laser energy sources, the laser energy sources being arranged on a first curved surface and being configured to emit laser energy towards a LIDAR target; and at least a first lens arranged in the optical path between the array of laser energy sources and the LIDAR target, wherein the first curved surface is positioned at an image plane of the first lens.

Optionally, the curvature of the first curved surface may follow a field curvature of the first lens.

Optionally, the field curvature of the first lens may comprise a curvature in a field of focus of the first lens.

Optionally, the first curved surface may comprise a curved wafer.

Optionally, the array of laser energy sources may comprise an array of vertical cavity surface emitting lasers (VCSELs) arranged in, on and/or integrated with the curved wafer.

Optionally, the curved wafer may comprise a cured semiconductor wafer.

Optionally, the curvature of the first curved surface may follow a Petzval surface of the first lens.

Optionally, the curvature of the first curved surface may comprise a spherical, elliptical, parabolic, or hyperbolic curvature.

Optionally, the curvature of the first curved surface may comprise a curvature in two dimensions.

Optionally, a face of the first curved surface facing the first lens may be concave.

Optionally, the laser energy sources may comprise edge emitters, LEDs and/or integrated laser energy sources arranged on the first curved surface.

According to a second aspect of the present disclosure, there is provided a LIDAR system, the LIDAR system comprising the LIDAR transmitter system of any of the aspect and embodiments described above.

Optionally, the LIDAR receiver system may comprise an array of photodetectors arranged on a second curved surface, the photodetectors may be configured to detect reflected energy from the LIDAR target; and a second lens may be arranged in the optical path between the LIDAR target and the array of photodetectors, the second curved surface may be positioned at an image plane of the second lens.

Optionally, the curvature of the second curved surface may follow a field curvature of the second lens.

Optionally, the field curvature of the second lens may comprises a curvature in a field of focus of the second lens.

Optionally, the second curved surface may comprise a curved wafer, the array of photodetectors arranged on the curved wafer, and the curvature of the second curved surface may follow a Petzval surface of the second lens.

According to a third aspect of the present disclosure, there is provided a method for emitting laser energy towards a LIDAR target, the method comprising: emitting laser energy from an array of laser energy sources towards a LIDAR target through a first lens arranged in the optical path between the array of laser energy sources and the LIDAR target, wherein the laser energy sources are arranged on a first curved surface, the first curved surface is positioned at an image plane of the first lens.

Optionally, the curvature of the first curved surface may follow a field curvature of the first lens.

Optionally, the field curvature of the first lens may comprise a curvature in a field of focus of the first lens.

According to a fourth aspect of the present disclosure, there is provided a method of manufacturing the LIDAR transmitter system of any of the aspects and embodiments described above, the method comprising: measuring a field curvature of a first lens;

arranging a plurality of laser energy sources as an array on a flat surface; heating the flat surface to increase malleability of the flat surface; applying a pressure to predetermined regions of the flat surface to convert the flat surface to a curved surface, the curvature of the curved surface following the field curvature of the first lens; cooling the curved surface; and positioning the curved surface at an image plane of the first lens.

Optionally, the field curvature of the first lens may comprise a curvature in a field of focus of the first lens.

Optionally, the flat surface may comprise a flat wafer.

Optionally, the array of laser energy sources may comprise an array of vertical cavity surface emitting lasers (VCSELs).

### BRIEF DESCRIPTION OF THE PREFERRED EMBODIMENTS

Some embodiments of the disclosure will now be described by way of example only and with reference to the accompanying drawings, in which:

FIGS. 1a-1b illustratively show a known LIDAR transmitter system.

FIGS. 2a-2b illustratively show a known LIDAR receiver.

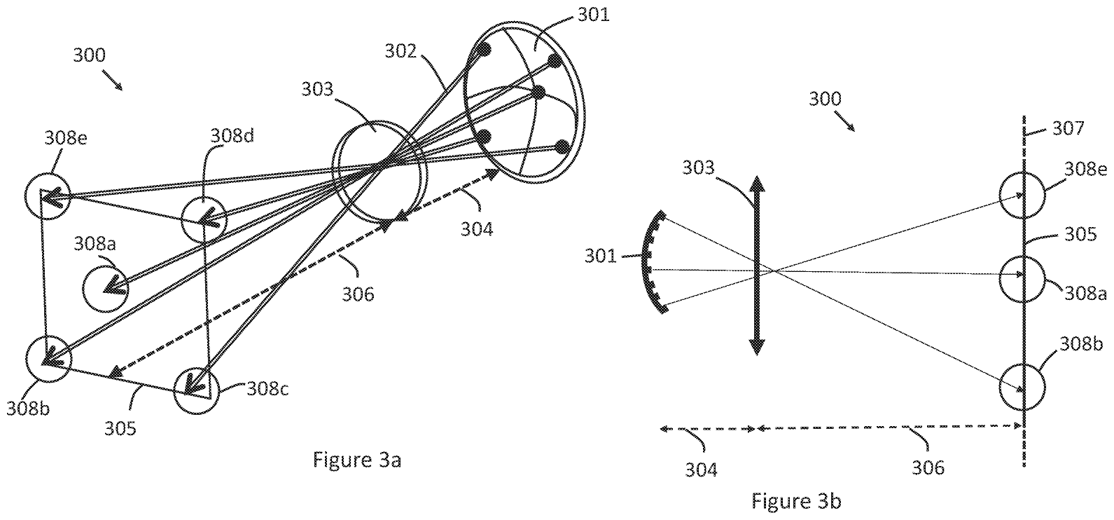

FIGS. 3a-3b illustratively show a LIDAR transmitter system in accordance with the present disclosure.

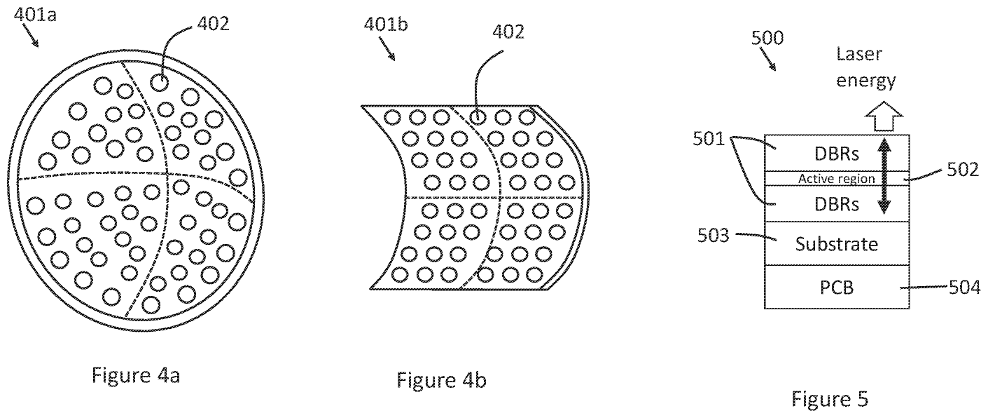

FIGS. 4a-4b illustratively show LIDAR transmitter systems in accordance with the present disclosure.

FIG. 5 illustratively shows a vertical cavity surface emitting laser in accordance with the present disclosure.

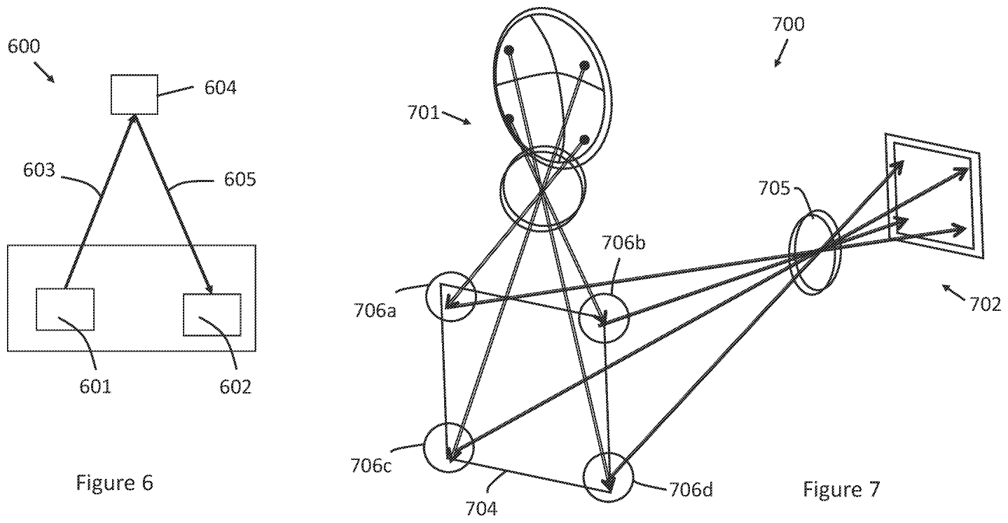

FIG. 6 illustratively shows a LIDAR system in accordance with the present disclosure.

FIG. 7 illustratively shows a LIDAR system in accordance with the present disclosure.

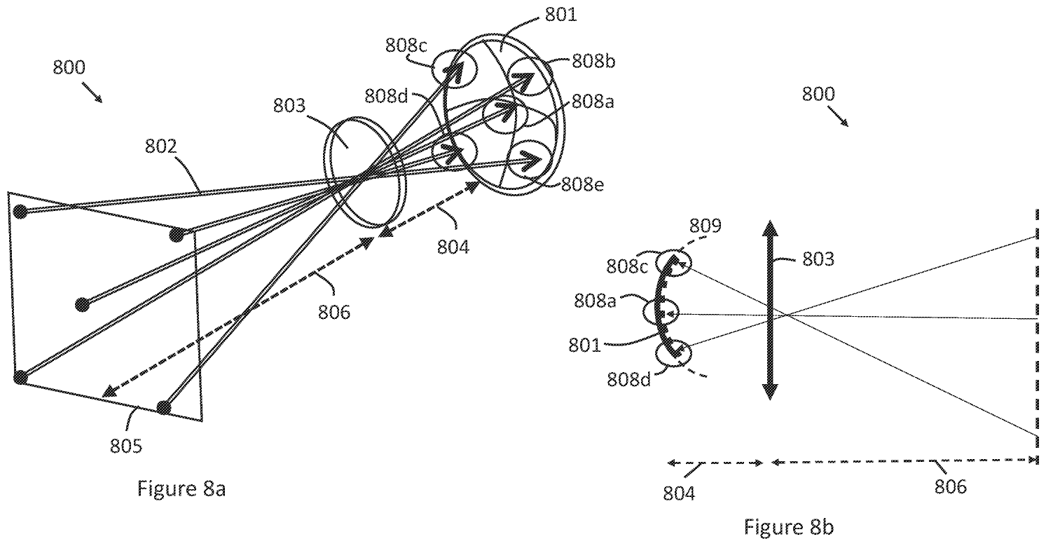

FIGS. 8a-8b illustratively show a LIDAR receiver in accordance with the present disclosure.

FIG. 9 illustratively shows a LIDAR system in accordance with the present disclosure.

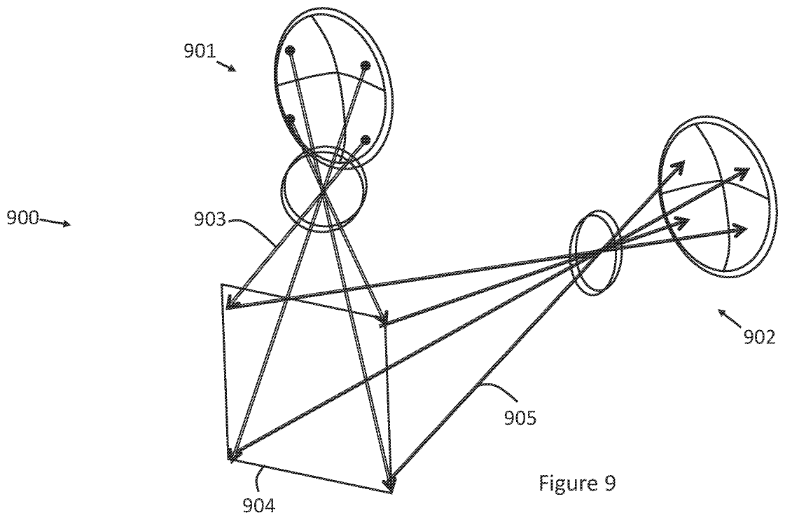

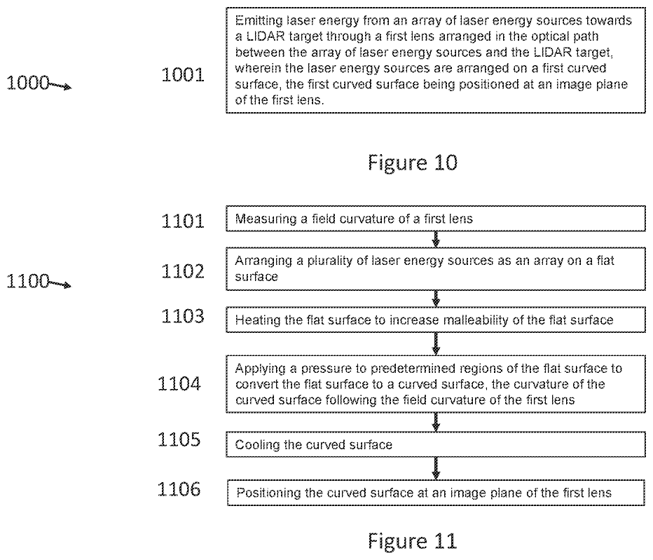

FIG. 10 illustratively shows a method in accordance with the present disclosure.

FIG. 11 illustratively shows a method in accordance with the present disclosure.

### DETAILED DESCRIPTION OF THE PREFERRED EMBODIMENTS

In general terms, this disclosure provides an array of laser energy sources arranged on a curved surface and being configured to emit laser energy towards a LIDAR target. A lens is arranged in the optical path between the array of laser energy sources and the LIDAR target. Instead of a lens, a lens system comprising a plurality of individual lenses may be used, but the disclosure equally applies to such systems. The curved surface on which the laser energy sources are arranged is positioned at an image plane of the first lens. The curvature of the curved surface follows a field curvature of the first lens.

Some examples of the solution provided by this disclosure are given in the accompanying figures

FIGS. 3a and 3b respectively show illustrations of a LIDAR transmitter system 300 comprising an array of laser energy sources arranged on a first curved surface 301.

The laser energy sources are configured to emit laser energy 302 towards a LIDAR target. A first lens 303 is arranged in the optical path between the array of laser energy sources and the LIDAR target, which may be situated for example a distance 306 from the lens. The first curved surface 301 is positioned at an image plane of the first lens, for example at a first effective focal distance 304 from the lens 303. The lens 303 causes a field curvature aberration as the laser energy passes through the lens. Accordingly, at the distance 306 at which the LIDAR target is positioned, the curvature of the image “plane” of the lens 303 is altered based on the strength of the field curvature effect caused by the lens 303. Accordingly, the field curvature aberration may be considered as a mapping of points on one surface to corresponding points on another surface having a modified curvature. As described above in relation to FIGS. 1 and 2, if the starting surface is flat, the mapped points define a curved surface as determined by the strength of the field curvature aberration. However, conversely, if the first surface has a curvature corresponding to the field curvature of the lens, the mapped points instead define a flat surface. In other words, the Petzval surface (i.e. the surface on which all points are in focus) may be flattened by modifying the curvature of the surface on which the laser sources of the LIDAR transmitter are arranged.

Accordingly, by configuring the curvature of the first curved surface 301 to follow the field curvature of the first lens, the detrimental effects the field curvature has on effective LIDAR range and resolution are compensated for and/or entirely countered.

In the example of FIGS. 3a and 3b, five example laser energy beams are shown emitting from the array of laser energy sources arranged on the curved surface 301, propagating through the lens 303 and hitting a LIDAR target. The curvature of the curved surface is configured to follow the field curvature of the lens 303 and accordingly, the Petzval surface 305 (i.e. the field in which all points are in focus) of this arrangement is flattened. Accordingly, at a distance 306 from the lens 303 all of the emitted laser energy is in focus when it intersect the Petzval surface 305 at points 308a, 308b, 308c, 308d, 308e. In other words, the Petzval surface now corresponds to and aligns with an ideal, flat image plane 307 as illustrated FIG. 307. In other words, the field of focus resulting from the combination of the field curvature aberration of the lens and the curved surface on which the laser energy sources are arranged is a flat surface.

With this arrangement, a LIDAR target situated at a distance 306 from the lens 303 will be illuminated across its whole visible surface with a laser energy beam that is wholly in focus, rather than with a laser energy beam which is only in focus along the optical axis. The above described problems of reduced effective LIDAR range and resolution are thereby solved. For example, if the effective LIDAR range and resolution of the LIDAR system 300 of FIG. 3a along the optical axis (i.e. along the central ray path 308a) is 60 meters and 0.1 degrees respectively, then the curvature of the curved surface 301 ensures the effective LIDAR range and resolution at the periphery of the emitted laser energy (i.e. along the other ray paths 308b, 308c, 308d, 308e) is also 60 meters and 0.1 degrees.

FIGS. 4a and 4b show example curved surfaces 401a, 401b on which an array of laser energy sources 402 are arranged. The curved surfaces 401a, 401b may be used as curved surfaces in the LIDAR transmitter array 300 illustrated in FIGS. 3a and 3b.

The curvature of the curved surfaces 401a, 401b is envisaged to be concave on the face facing the lens and may comprise, for example, a spherical curvature 401a, a parabolic curvature 401b, an elliptical curvature, or hyperbolic curvature. The curvature may comprise a curvature in two different dimensions, as shown in the example of FIG. 4a, or may comprise a curvature in only one dimension as shown in FIG. 4b. It is envisaged that a curvature in only one dimension may be of use in LIDAR applications where only range in a single plane is to be determined. For example, in object detection and collision avoidance in self-driving vehicles, only objects in a single, horizontal plane in front of the vehicle may be of relevance. Accordingly, in such a LIDAR application, only the effect of the field curvature in the horizontal dimension may need to be compensated for. Thus, the curvature of the curved surface on which the laser energy sources are arranged may be only in the corresponding horizontal direction.

FIG. 5 shows an illustration of a vertical-cavity surface-emitting laser (VCSEL) 500 which may be used as one or more of the laser energy sources described above in relation to FIGS. 3-4. The VCSEL comprises a plurality of distributed Bragg reflector (DBR) layers 501 positioned on either side of an active region 502, for example comprising one or more quantum wells, for laser energy generation and resonance between the DBR layers 501. The DBR layers 501 and active region 502 may be arranged on a substrate 503, which in turn may be arranged no a printed circuit board (PCB) 504. The VCSEL 500 of FIG. 5 is a top-emitting VCSEL however it is also envisaged that bottom-emitting VCSELs may be used in present disclosure. Alternatively, it is also envisaged that the laser energy sources of the LIDAR transmitter system described herein may additionally and/or alternatively comprise comprise edge emitters, LEDs and/or integrated energy sources.

FIG. 6 illustratively shows a LIDAR system 600 comprising a LIDAR transmitter system 601 such as that described above in connection with FIGS. 2-5 and a LIDAR receiver system 602. The LIDAR transmitter system 601 is configured to emit laser energy 603 towards a LIDAR target 604. Reflected laser energy 605 propagates towards the LIDAR receiver system 602 where it is detected and used to calculate a distance from the LIDAR system 600 to the LIDAR target 604 for example using a time-of-flight calculation.

The LIDAR system 600 may operate as a flash LIDAR where the LIDAR transmitter system 601 emits laser pulses (for example sub-nanosecond light pulses), or as a scanning LIDAR where the LIDAR transmitter system 601 emits a continuous, directed beam.

The LIDAR receiver system 602 may comprise a plurality of photodetectors, for example photodiodes, such as pin diodes, single photon avalanche diodes, avalanche diodes, or phototransistors configured to detect the laser energy 605 reflected from the LIDAR target 604. Each photodetector of the LIDAR receiver system 604 acts as a detection pixel typically corresponding to one laser energy source in the array of the LIDAR transmitter system 601. The one-to-one pixel-emitter correspondence may be used to calculating a time-of-flight histogram which may be used to detect and compensate for any internal reflections from, for example, optional cover glass of the LIDAR system 600, or any cross-talk between laser energy sources of the array and a plurality of different detection pixels.

By using a LIDAR transmitter system 600 such as that described in relation to FIGS. 2-5, the output laser energy 603 is in focus at the plane of the LIDAR target 604. Accordingly, the effective LIDAR range and resolution of the output beam is consistent across its entire area of illumination at the LIDAR target 604 because the beam intensity and divergence is consistent at that distance and there is no drop off at the periphery of the beam.

FIG. 7 illustratively shows a LIDAR system 700 which may be an example of the LIDAR system 600 of FIG. 6. The example LIDAR system of FIG. 7 comprises a LIDAR transmitter system 701 of the type described in relation to FIGS. 2-5 and a LIDAR receiver system 702 such as that described in relation to FIG. 6. The LIDAR transmitter system 701 is configured to emit laser energy (shown with illustrative ray paths) 706a, 706b, 706c, 706d towards a LIDAR target 704. By using a LIDAR transmitter system 701 according to the present disclosure, the laser energy is in focus over its whole area of illumination when it hits the LIDAR target 704. Accordingly, the beam intensity and divergence is consistent across the whole area of illumination. Thus, when the reflected energy is detected at the LIDAR receiver system 702, there is no drop of in signal strength or quality at the periphery of the detected laser energy beam. As described above, this is in contrast to known LIDAR systems where the field curvature of the lens of the LIDAR transmitter prevents the periphery of the output beam being in focus at the LIDAR target, reducing the beam intensity of the periphery of the beam when it hits the LIDAR target, thereby reducing the strength of any reflected signal detected by the LIDAR receiver system and resulting in a reduced effective LIDAR range and resolution at the periphery of the output beam.

In the example configuration of FIG. 7, the LIDAR receiver system 702 comprises an array of photodetectors arranged on a flat surface and a lens 705 arranged in the optical path between the LIDAR target 704 and the array of photodetectors. The energy reflected from the LIDAR target 704 travels through the lens 705 and hits the array of photodetectors of the LIDAR receiver system 702. In the example of FIG. 7, four illustrative ray paths 706a, 706b, 706c, 706d shown between the LIDAR transmitter system 701 and the LIDAR receiver system 702. Whilst the array of photodetectors in the configuration of FIG. 7 are shown to be arranged on a flat surface, it is envisaged that the array may also be arranged on a curved surface in order to compensate for and/or entirely counter the effect of the field curvature of the lens 705 of the LIDAR receiver system 702 in the same way that the curved surface of the LIDAR transmitter system 701 compensates for the field curvature of the lens of the LIDAR transmitter system 701. In this way, any further reductions in effective LIDAR range and/or resolution caused by the lens field curvature in the LIDAR receiver system 702 can be minimised and/or eliminated.

FIGS. 8a and 8b illustratively show a LIDAR receiver system 800 which may be used as the LIDAR receiver system of FIGS. 6-7. The LIDAR receiver system 800 comprises an array of photodetectors arranged on a second curved surface 801, the photodetectors configured to detect reflected energy 802 from a LIDAR target 805 illuminated by a LIDAR transmitter system, for example of the type described in FIGS. 2-7. The LIDAR receiver system 800 further comprises a lens 803 arranged in the optical path between the LIDAR target 805, situated at a distance 806 from the lens 803, and the array of photodetectors arranged on the curved surface 801. The energy 802 reflected from the LIDAR target 805 travels through the lens 803, hits the array of photodetectors of the LIDAR receiver system 800 on the curved surface 801. In the example of FIG. 8, five illustrative ray paths 808a, 808b, 808c, 808d, 808e are shown between the LIDAR target 805 and the LIDAR receiver system 800. The second curved surface 801 is positioned at an image plane of the lens 803, for example at an effective focal length 804 of the lens 803. The curvature of the second curved surface 801 follows a field curvature of the second lens, thereby compensating for and/or entirely countering the effect of the field curvature aberration on the field of focus of the lens in the same way as described above in relation to the LIDAR transmitter system described herein. In other words, the curvature of the second curved surface follows the Petzval surface or curved field of focus 809 of the lens 803.

As shown in FIG. 8b, the effects of the field curvature aberration of the lens 803 are compensated for because the curvature of the curved surface 801 on which the array of photodetectors is arranged ensures the photodetectors are positioned in the curved image “plane” (i.e. curved field of focus) of the lens 803, ensuring the energy detected at each photodetector is in focus. In this way, any effects of the field curvature aberration on the effective LIDAR range and resolution at the LIDAR receiver system 800 are minimised and/or eliminated.

FIG. 9 illustratively shows a LIDAR system 900 which may be an example configuration of the LIDAR system 600 of FIG. 6. The LIDAR system 900 comprises a LIDAR transmitter system 901 such as that described above in relation to FIGS. 2-5 and a LIDAR receiver system 902 such as that described in relation to FIGS. 8a-8b. The LIDAR transmitter system 901 is configured to emit laser energy 903 towards a LIDAR target 904. Reflected laser energy 905 propagates towards the LIDAR receiver system 902 where it is detected and used to calculate a distance from the LIDAR system 900 to the LIDAR target 904 for example using a time-of-flight calculation. As described above in relation to FIG. 6, the LIDAR system 900 may operate as a flash LIDAR where the LIDAR transmitter system 901 emits laser pulses (for example sub-nanosecond light pulses), or as a scanning LIDAR where the LIDAR transmitter system 901 emits a continuous, directed beam.

The LIDAR system 900 of FIG. 9 is particularly advantageous in that the effects of field curvature from both the lens of the LIDAR transmitter system 901 and the lens of the LIDAR receiver system 902 are minimised and/or countered entirely. Accordingly, the effective LIDAR range and resolution of the LIDAR system 900 of FIG. 9 is consistently higher across the entire field of view (i.e. area of illumination) of the LIDAR target 904 than for known LIDAR systems which suffer from a drop off in effective LIDAR range and resolution drop off at the periphery of the field of view.

FIG. 10 shows a flowchart showing method steps in accordance with the present disclosure. In general terms, the method is directed to emitting laser energy towards a LIDAR target and may be used in connection with the above described LIDAR transmitter system, LIDAR receiver system and LIDAR system. The method 1000 comprises emitting 1001 laser energy from an array of laser energy sources towards a LIDAR target through a first lens arranged in the optical path between the array of laser energy sources and the LIDAR target. The laser energy sources are arranged on a first curved surface, the first curved surface being positioned at an image plane of the first lens, and the curvature of the curved surface following a field curvature of the first lens. Performing the above described method steps ensures the effects of the field curvature of the lens are reduced and/or eliminated.

It is envisaged for all of the embodiments described above that the curved surface of the LIDAR transmitter system may comprise a curved wafer (for example, a wafer of cured semiconducting material) on which the laser energy sources have been arranged, for example during or as part of the manufacturing process in which the laser emitters are integrated into or onto the surface at wafer-level which may comprise using a curing process such as heating and/or cooling. For example, where the array of laser energy sources comprises an array of VCSELs (for example VCSELs of the type shown in FIG. 5), the curved surface may comprise a curved semiconductor wafer on which the VCSELs are arranged and/or into which the VCSELs have been integrated during manufacture of the wafer.

In general terms, during manufacture of the LIDAR transmitter system described herein, it is envisaged that the array of laser energy sources will be arranged on a flat surface first (for example, a flat wafer with integrated VCSELs may be manufactured using an epitaxial process) before a curvature is formed in the surface, for example using a thermal process during which pressure is applied to predetermined regions of the surface. Accordingly, FIG. 11 shows a flowchart showing method steps in accordance with the present disclosure. The method 1100 shown in FIG. 11 is a method of manufacturing the LIDAR transmitter system described herein, and comprises measuring 1101 a field curvature of a first lens, arranging 1102 a plurality of laser energy sources as an array on a flat surface, heating 1103 the flat surface to increase the malleability of the flat surface, and applying 1104 a pressure to predetermined regions of the flat surface to convert the flat surface to a curved surface. The curvature of the curved surface following the measured field curvature of the first lens. Once the curvature has been formed, the curved surface is cooled 1105 to retain the curved shape and the completed curved surface (and array of laser energy sources arranged thereon) is positioned 1106 at an image plane of the first lens.

An advantage provided by the above described method of manufacture is that existing production lines do not need to be changed as the additional step of introducing the curvature may be performed separately to the manufacture of the flat wafer and laser energy source array. Accordingly, the present method is a particularly cost-effective way of producing advantageous LIDAR transmitter systems.

Embodiments of the present disclosure can be employed in many different applications including, for example, for 3D facial recognition, proximity detection, presence detection, object detection, distance measurements, and/or collision avoidance for example in the field of automotive vehicles or drones, and other fields and industries.

### LIST OF REFERENCE NUMERALS

100 known LIDAR transmitter system
101 laser source
102 laser energy
103 lens
104 effective focal length
105 ideal, flat image plane
106 distance to lens
107 curved image “plane”/Petzval surface
108a-e ray paths
200 known LIDAR receiver system
201 array of photodetectors 201
202 reflected energy
203 lens
204 effective focal length
205 LIDAR target
206 distance to lens
208a-e ray paths
209 ideal, flat image plane
210 curve image “plane”/Petzval surface
300 LIDAR transmitter system
301 first curved surface
302 laser energy
303 first lens
304 first effective focal distance
305 flattened Petzval surface/field of focus
306 distance from lens
307 ideal, flat image plane
308a-e ray paths
401a example curves surface
401b example curved surface
402 array of laser energy sources
500 vertical-cavity surface-emitting laser (VCSEL)
501 distributed Bragg reflector (DBR) layers
502 active region
503 substrate
504 printed circuit board (PCB)
600 LIDAR system
601 LIDAR transmitter system
602 LIDAR receiver system
603 emitted laser energy
604 LIDAR target
605 reflected energy
700 LIDAR system
701 LIDAR transmitter system
702 LIDAR receiver system
705 lens
706a-d ray paths
800 LIDAR receiver system
801 second curved surface
802 reflected energy
803 lens
804 effective focal length
805 LIDAR target
806 distance from lens
808a-e ray paths
809 Petzval surface or curved field of focus
900 LIDAR system
901 LIDAR transmitter system
902 LIDAR receiver system
903 emitted laser energy
904 LIDAR target
905 reflected energy
1000 method of emitting laser energy towards a LIDAR target
1001 emitting laser energy
1100 method of manufacturing a LIDAR transmitter system
1101 measuring a field curvature
1102 arranging a plurality of laser energy sources
1103 heating the flat surface
1104 applying a pressure
1105 cooling the curved surface
1106 positioning the curved surface

The skilled person will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in any embodiments, whether alone or in any appropriate combination with any other feature disclosed or illustrated herein.

For example, whilst the term lens has been used herein in the singular, it is envisaged that the present disclosure and the advantages it provides may be applied equally to more complex optical systems comprising more than one lens, and/or mirrors or other optical components that may result in a more complex shaped field curvature arising from the optical system. For example, an optical system with multiple lenses, one or more mirrors and/or other optical components may cause the resulting field curvature of the optical system to have a wavy (or other more complex shaped) field curvature. Accordingly, the curvature of the curved surface described herein may follow the more complex shaped field curvature to provide the same advantages as described herein.

1. A LIDAR transmitter system comprising:
an array of laser energy sources, the laser energy sources being arranged on a first curved surface and being configured to emit laser energy towards a LIDAR target; and
at least a first lens arranged in the optical path between the array of laser energy sources and the LIDAR target,
wherein the first curved surface is positioned at an image plane of the first lens.

2. The LIDAR transmitter system according to claim 1, wherein the curvature of the first curved surface follows a field curvature of the first lens.

3. The LIDAR transmitter system according to claim 2, wherein the field curvature of the first lens comprises a curvature in a field of focus of the first lens.

4. The LIDAR transmitter system according to claim 1, wherein the first curved surface comprises a curved wafer.

5. The LIDAR transmitter system according to claim 4, wherein the array of laser energy sources comprises an array of vertical cavity surface emitting lasers (VCSELs) arranged in, on and/or integrated with the curved wafer.

6. The LIDAR transmitter system according to claim 5, wherein the curved wafer comprises a cured semiconductor wafer.

7. The LIDAR transmitter system according to claim 1, wherein the curvature of the first curved surface follows a Petzval surface of the first lens.

8. The LIDAR transmitter system according to claim 7,
wherein the curvature of the first curved surface comprises a spherical, elliptical, parabolic, or hyperbolic curvature.

9. The LIDAR transmitter system according to claim 1 The LIDAR transmitter system according to claim,
wherein the curvature of the first curved surface comprises a curvature in two dimensions.

10. The LIDAR transmitter system according to claim 1,
wherein a face of the first curved surface facing the first lens is concave.

11. The LIDAR transmitter system according to claim 1, wherein the laser energy sources comprise edge emitters, LEDs and/or integrated laser energy sources arranged on the first curved surface.

12. A LIDAR system, the LIDAR system comprising:
the LIDAR transmitter system of claim 1; and
a LIDAR receiver system.

13. The LIDAR system according to claim 12,
wherein the LIDAR receiver system comprises:
an array of photodetectors arranged on a second curved surface, the photodetectors configured to detect reflected energy from the LIDAR target; and
a second lens arranged in the optical path between the LIDAR target and the array of photodetectors,
wherein the second curved surface is positioned at an image plane of the second lens.

14. The LIDAR system according to claim 13, wherein the curvature of the second curved surface follows a field curvature of the second lens.

15. The LIDAR system according to claim 14, wherein the field curvature of the second lens comprises a curvature in a field of focus of the second lens.

16. The LIDAR system according to claim 12,
wherein the second curved surface comprises a curved wafer, the array of photodetectors arranged on the curved wafer, and
wherein the curvature of the second curved surface follows a Petzval surface of the second lens.

17. A method for emitting laser energy towards a LIDAR target, the method comprising:
emitting laser energy from an array of laser energy sources towards a LIDAR target through a first lens arranged in the optical path between the array of laser energy sources and the LIDAR target,
wherein the laser energy sources are arranged on a first curved surface, the first curved surface is positioned at an image plane of the first lens.

18. The method according to claim 17, wherein the curvature of the first curved surface follows a field curvature of the first lens.

19. The method according to claim 18, wherein the field curvature of the first lens comprises a curvature in a field of focus of the first lens.

20. A method of manufacturing the LIDAR transmitter system of claim 1, the method comprising:
measuring a field curvature of a first lens;
arranging a plurality of laser energy sources as an array on a flat surface;
heating the flat surface to increase malleability of the flat surface;
applying a pressure to predetermined regions of the flat surface to convert the flat surface to a curved surface, the curvature of the curved surface following the field curvature of the first lens;
cooling the curved surface; and
positioning the curved surface at an image plane of the first lens.

21. The method according to claim 20, wherein the field curvature of the first lens comprises a curvature in a field of focus of the first lens.

22. The method according to claim 20, wherein the flat surface comprises a flat wafer.

23. The method according to claim 20, wherein the array of laser energy sources comprises an array of vertical cavity surface emitting lasers (VCSELs).
